(19) United States
(12) Patent Application Publication
(10) Pub. No.: US 2012/0080222 A1
(43) Pub. Date: Apr. 5, 2012

(54) CIRCUIT BOARD INCLUDING EMBEDDED DECOUPLING CAPACITOR AND SEMICONDUCTOR PACKAGE THEREOF

(75) Inventors: Yong-Hoon Kim, Suwon-si (KR); Hee-Seok Lee, Yongin-si (KR); Ji-Hyun Lee, Seoul (KR)

(73) Assignee: SAMSUNG ELECTRONICS CO., LTD., Suwon-si (KR)

(21) Appl. No.: 13/247,526

(22) Filed: Sep. 28, 2011

(30) Foreign Application Priority Data
Oct. 1, 2010 (KR) 10-2010-0095924

(51) Int. Cl. H05K 1/16

(52) U.S. Cl. 174/260

(57) ABSTRACT

A circuit board including an embedded decoupling capacitor and a semiconductor package thereof are provided. The circuit board may include a core layer including an embedded decoupling capacitor, a first build-up layer at one side of the core layer, and a second build-up layer at the other side of the core layer, wherein the embedded decoupling capacitor includes a first electrode and a second electrode, the first build-up layer includes a first via contacting the first electrode, and the second build-up layer includes a second via contacting the first electrode.

### CROSS-REFERENCE TO RELATED APPLICATION

This application claims priority under 35 U.S.C. §119 to Korean Patent Application No. 10-2010-0095924 filed on Oct. 1, 2010 in the Korean Intellectual Property Office, the entire contents of which are herein incorporated by reference.

### BACKGROUND

1. Field

Example embodiments relate to a circuit board including an embedded decoupling capacitor and a semiconductor package thereof.

2. Description of the Related Art

In order to improve characteristics of a semiconductor device, it is desirable to increase the speed of a memory controller and to improve power integrity (PI).

### SUMMARY

A decoupling capacitor may be disposed at various locations of a semiconductor device. For example, the decoupling capacitor may be disposed on a main board in the form of a surface mounting capacitor (SMT) separately from a semiconductor package. Alternatively, the decoupling capacitor may be mounted on a surface of a circuit board of a semiconductor package.

In detail, mounting the decoupling capacitor on a surface of the main board may impose limitations on improvement of the PI characteristic because the decoupling capacitor is far from the semiconductor package. In particular, in a case of a hand-held phone (HHP) in which various components are mounted on both surfaces of a main board, a decoupling capacitor may be mounted on one side of the main board, making it more difficult to improve the PI characteristic.

In a case of mounting the decoupling capacitor on a circuit board of a semiconductor package, the resulting structure may make the semiconductor package bulky, thus, such an arrangement may not be suitable for miniaturization of the semiconductor package.

Accordingly, example embodiments propose a method of embedding a decoupling capacitor in a circuit board of a semiconductor package and a circuit board having the embedded decoupling capacitor.

Example embodiments provide a circuit board which can improve power integrity (PI).

Example embodiments also provide a semiconductor package which can improve power integrity (PI).

These and other objects of example embodiments will be described in or be apparent from the following description.

In accordance with example embodiments, a circuit board may include a core layer including an embedded decoupling capacitor, a first build-up layer on one side of the core layer, and a second build-up layer on another side of the core layer, wherein the embedded decoupling capacitor includes a first electrode and a second electrode, the first build-up layer includes a first via contacting the first electrode, and the second build-up layer includes a second via contacting the first electrode.

In accordance with example embodiments, a circuit board may include a core layer, a first buildup layer, and a second buildup layer. In example embodiments, the core layer may include a decoupling capacitor, the decoupling capacitor may include a first electrode, a second electrode, and an insulation body between the first electrode and the second electrode. The first buildup layer may be on an upper surface of the core layer and the first build up layer may include a first wire and a second wire, the first wire being connected to the first electrode by a first via and the second wire being connected to the second electrode by a second via. The second buildup layer may be on a lower surface of the core layer. The second build up layer may include a third wire and a fourth wire, the third wire being connected to the first electrode by a third via and the fourth wire being connected to the second electrode by a fourth via.

In accordance with example embodiments, there is provided a circuit board including a core layer having an embedded decoupling capacitor, a first build-up layer formed at one side of the core layer, and a second build-up layer formed at the other side of the core layer, wherein the embedded decoupling capacitor includes a first electrode and a second electrode extending in a direction in which they extend through the core layer, the first build-up layer includes a first via contacting the first electrode, and the second build-up layer includes a second via contacting the first electrode.

In accordance with example embodiments, there is provided a circuit board including a core layer including a core insulation layer having an embedded decoupling capacitor including a first electrode and a second electrode, and a first plane of a first voltage, formed at one or the other side of the core insulation layer, a first build-up layer formed at one side of the core layer, a second build-up layer formed at the other side of the core layer, and a first topmost wire formed on the first build-up layer so as not to overlap with the first electrode and electrically connected to the first plane, wherein the first electrode is electrically connected to the first plane through a first connection wire formed in the second build-up layer.

In accordance with example embodiments, there is provided a semiconductor package including the circuit board, and a semiconductor chip on the circuit board.

### BRIEF DESCRIPTION OF THE DRAWINGS

The above and other features and advantages of the present invention will become more apparent by describing in detail example embodiments thereof with reference to the attached drawings in which:

FIG. 1 is a cross-sectional view of a circuit board according to example embodiments;

FIG. 2 is a cross-sectional view of a semiconductor package including the circuit board shown in FIG. 1;

FIG. 3 is a partly exploded perspective view of an embedded decoupling capacitor shown in FIGS. 1 and 2;

FIG. 4 is a perspective view of an insulation body of an embedded decoupling capacitor;

FIG. 5 illustrates the operation (specifically, voltage transfer) of a semiconductor package according to example embodiments;

FIG. 6 is a cross-sectional view of a circuit board and a semiconductor package according to example embodiments;

FIG. 7 is a cross-sectional view of a circuit board and a semiconductor package according to example embodiments;

FIG. 8 is a cross-sectional view of a circuit board according to example embodiments; and

FIGS. 9 to 11 illustrate application examples of semiconductor packages according to example embodiments.

### DETAILED DESCRIPTION

Example embodiments will be described more fully hereinafter with reference to the accompanying drawings, in which example embodiments are shown. The present invention may, however, be embodied in many different forms and should not be construed as limited to example embodiments as set forth herein. Rather, example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers that may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

While example embodiments will be described in connection with a circuit board having six conductive layers, the invention is not limited thereto. Rather, the invention may be applied to a circuit board having multiple conductive layers, for example, four, eight, ten or more conductive layers.

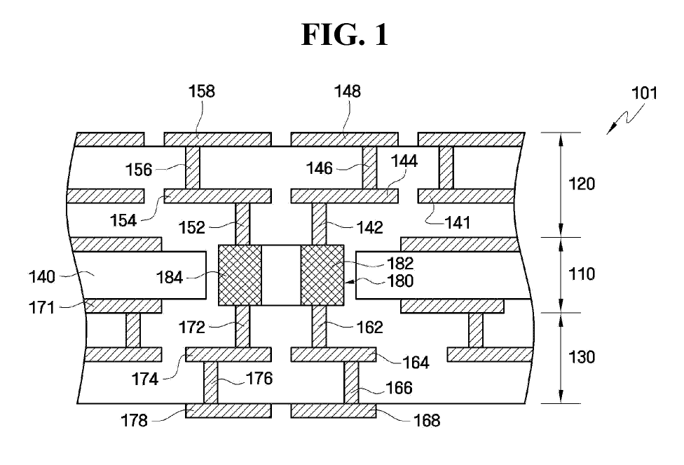

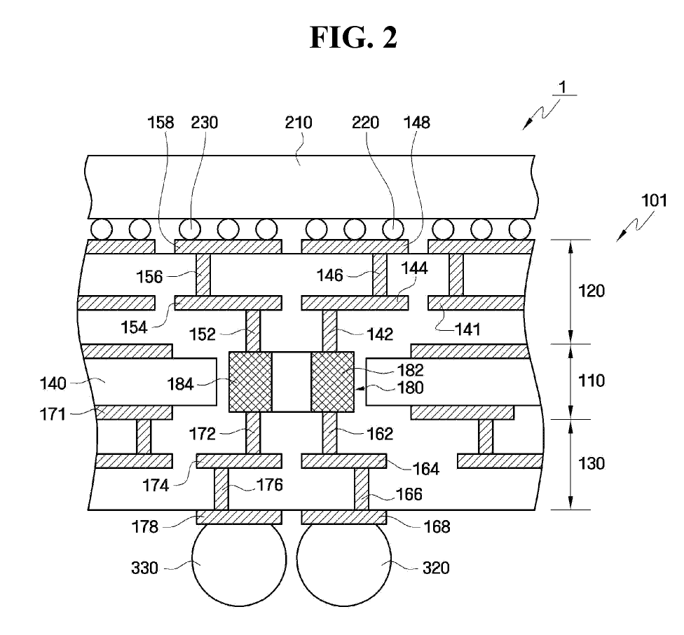

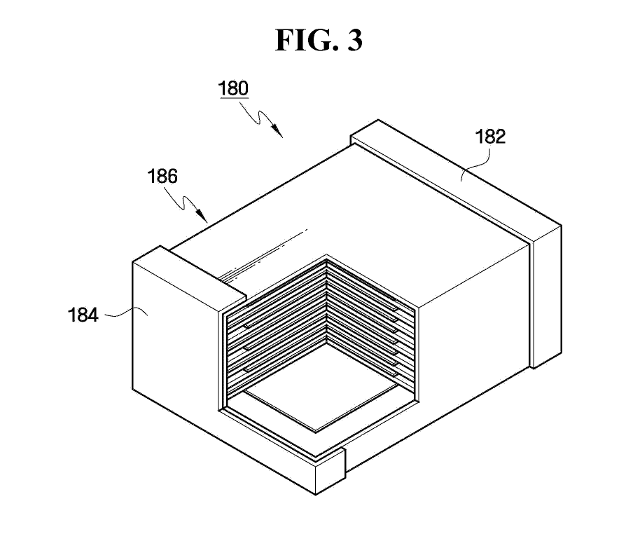

FIG. 1 is a cross-sectional view of a circuit board according to example embodiments, FIG. 2 is a cross-sectional view of a semiconductor package including the circuit board shown in FIG. 1, FIG. 3 is a partly exploded perspective view of an embedded decoupling capacitor shown in FIGS. 1 and 2, and FIG. 4 is a perspective view of an insulation body of an embedded decoupling capacitor.

In accordance with example embodiments, a circuit board 101 may include a core layer 110, a build-up layer 120 formed at one side of the core layer 110, and a second build-up layer 130 formed at the other side of the core layer 110, as shown in FIGS. 1 and 2.

The core layer 110 may include a core insulation layer 140 having an embedded decoupling capacitor 180 formed therein, a first plane 141 for a first voltage, formed at one side of the core insulation layer 140, and a second plane 171 for a second voltage, formed at the other side of the core insulation layer 140. For example, the first voltage may be a ground voltage GND, and the second voltage may be a power voltage POWER.

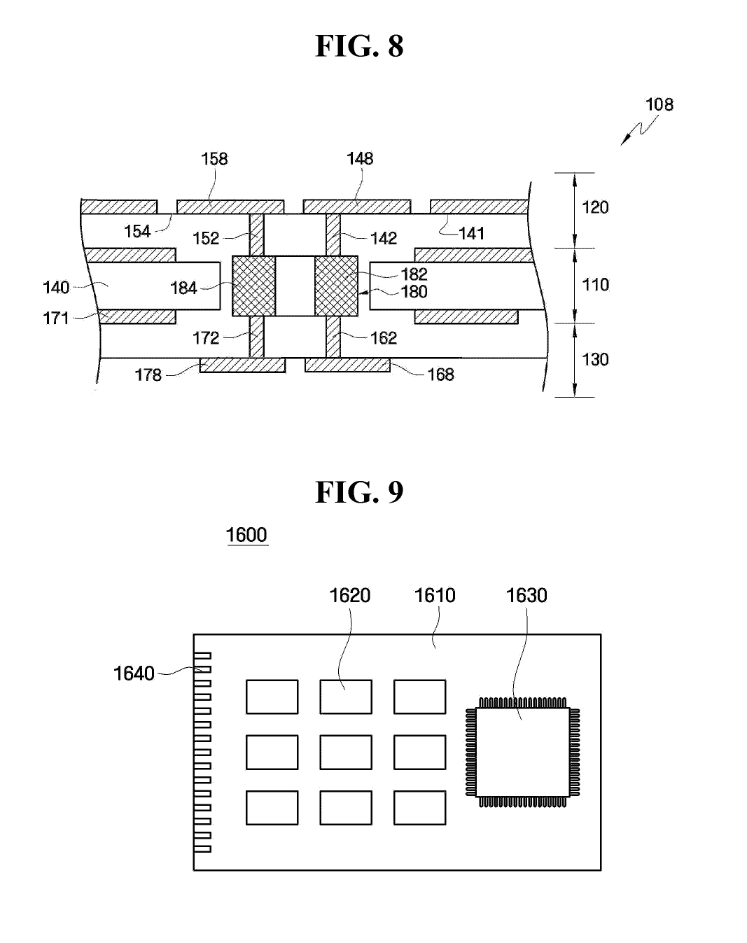

As shown, in a case where the circuit board 101 includes six conductive layers, two lower layers and two upper layers may be primarily used for transfer of signals, and two middle layers may be primarily used for transfer of voltages (e.g., a ground voltage and/or a power voltage). In a case where the circuit board 101 includes four conductive layers, the topmost layer and the bottommost layer may be primarily used for transfer of signals, and two middle layers may be primarily used for transfer of voltages (see FIG. 8).

In example embodiments, the embedded decoupling capacitor 180 may be formed within the core layer 110. The embedded decoupling capacitor 180 may include a first electrode 182 and a second electrode 184 extending in a direction in which they extend through the core insulation layer 140.

The embedded decoupling capacitor 180 may not overlap with the first plane 141 or the second plane 171 because a portion of the core layer 110 may be removed and the embedded decoupling capacitor 180 may be formed within the core layer 110.

The embedded decoupling capacitor 180 may be, for example, a multi layer chip capacitor (MLCC), but not limited thereto.

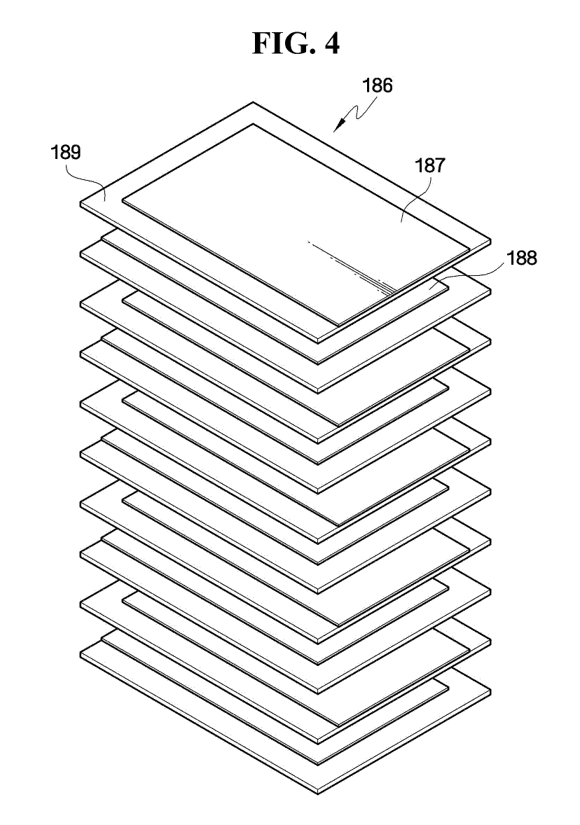

Referring to FIGS. 3 and 4, the MLCC-type embedded decoupling capacitor 180 may include an insulation body 186 between the first electrode 182 and the second electrode 184. The insulation body 186 may include multi-layered insulation layers 189, multi-layered first inner electrodes 187 formed between the multi-layered insulation layers 189 and extending to be connected to the first electrode 182, and multi-layered second inner electrodes 188 formed between the multi-layered insulation layers 189 and connected to the second electrode 184. That is to say, since the first inner electrodes 187, the insulation layers 189 and second inner electrodes 188 may be alternately disposed in the insulation body 186, the MLCC may have large capacitance even in a narrow area.

Referring back to FIGS. 1 and 2, the first build-up layer 120 may include a plurality of vias 142, 146, 152, and 156, and multi-layered wires 144, 148, 154, and 158. The second build-up layer 130 may include a plurality of vias 162, 166, 172, and 176, and multi-layered wires 164, 168, 174, and 178.

In example embodiments, a first topmost wire 148 may be connected to a semiconductor chip 210 through a first bump 220, and a second topmost wire 158 may be connected to the semiconductor chip 210 through a second bump 230.

The first bottommost wire 168 may be connected to a first external connection terminal 320 in the form of, e.g., a ball, as shown in FIG. 2, and the second bottommost wire 178 may be connected to a second external connection terminal 330.

In particular, the first electrode 182 may contact vias 142 and 162 in both upward and downward directions. Specifically, the first electrode 182 may contact the first via 142 formed in the first build-up layer 120 and contact the second via 162 formed in the second build-up layer 130. With this configuration, the first bottommost wire 168 of the second build-up layer 130 and the first topmost wire 148 of the first build-up layer 120 may be connected to each other through the first electrode 182. That is to say, the first electrode 182 may serve as a wire.

Likewise, the second electrode 184 may contact vias 152 and 172 in both upward and downward directions. Specifically, the second electrode 184 may contact the third via 152 formed in the first build-up layer 120 and contact the fourth via 172 formed in the second build-up layer 130. With this configuration, the second bottommost wire 178 of the second build-up layer 130 and the second topmost wire 158 of the first build-up layer 120 may be connected to each other through the second electrode 184. That is to say, the second electrode 184 may serve as a wire.

When the circuit board 101 is viewed from above, the first bottommost wire 168 (or the first external connection terminal 320) may overlap with the first electrode 182, and the second bottommost wire 178 (or the second external connection terminal 330) may overlap with the second electrode 184 because the second via 162 may contact a lower portion of the first electrode 182 and the fourth via 172 may contact a lower portion of the second electrode 184.

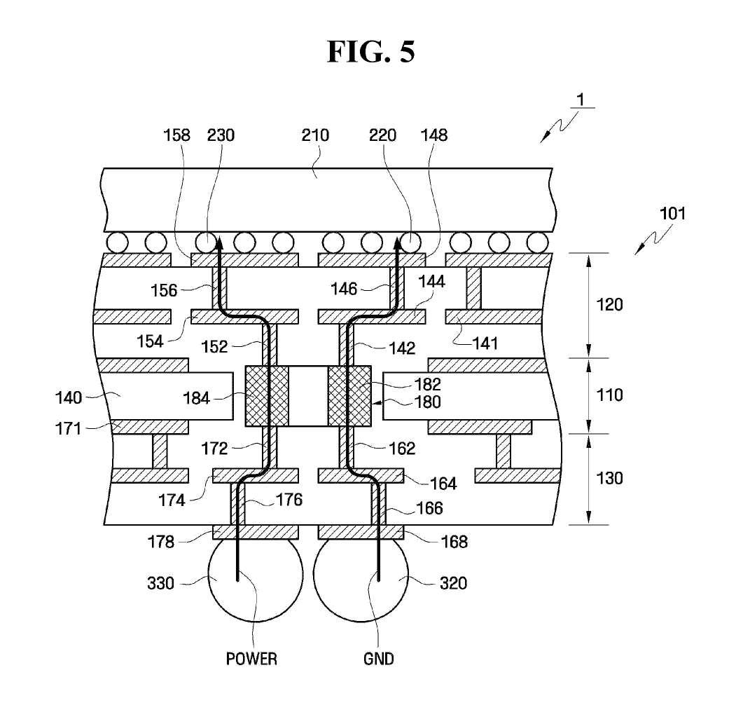

FIG. 5 illustrates the operation (specifically, voltage transfer) of a semiconductor package according to example embodiments.

Referring to FIG. 5, the first electrode 182 and the second electrode 184 of the embedded decoupling capacitor 180 may be used as voltage transfer paths.

As shown in FIG. 5, a first voltage (for example, a ground voltage GND) may be transferred to the semiconductor chip 210 through the first external connection terminal 320, the first bottommost wire 168, the via 166, the wire 164, the via 162, the first electrode 182, the via 142, the wire 144, the via 146, the first topmost wire 148 and the bump 220.

A second voltage (for example, a power voltage POWER) may be transferred to the semiconductor chip 210 through the second external connection terminal 330, the second bottommost wire 178, the via 176, the wire 174, the via 172, the second electrode 184, the via 152, the wire 154, the via 156, the second topmost wire 158 and the bump 230.

The first electrode 182 and the second electrode 184 of the embedded decoupling capacitor 180 may be used as voltage transfer paths (that is, as wire-like paths), and the voltage transfer paths ranging from the first and second external connection terminals 320 and 330 to the semiconductor chip 210 may be relatively short. In this case, that is, if the voltage transfer paths are relatively short, the voltage can be stably supplied, so that the PI characteristic can be improved.

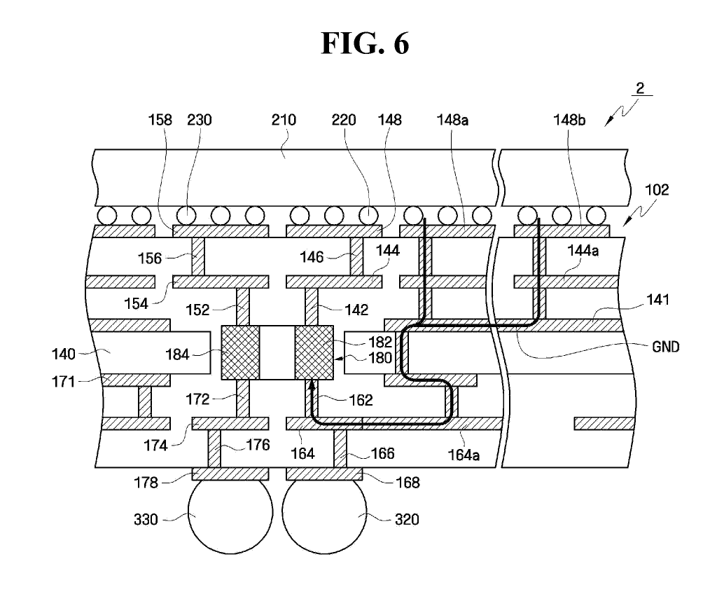

FIG. 6 is a cross-sectional view of a circuit board and a semiconductor package according to example embodiments. The following description will focus on differences between the circuit boards and the semiconductor packages according to the first and second embodiments.

Referring to FIG. 6, an embedded decoupling capacitor 180 may be disposed to improve the PI characteristic by supplying a stable voltage to a semiconductor chip 210. Therefore, the inductance or resistance between a voltage terminal of the semiconductor chip 210 and the embedded decoupling capacitor 180 may be relatively small.

In the semiconductor package 2 according to example embodiments, a first plane 141 in the circuit board 102 may be used as a voltage transfer path.

As shown in FIG. 6, a plurality of third topmost wires 148a and 148b not overlapping with a first electrode 182 may be electrically connected to the first plane 141 through a via. The first plane 141 may be electrically connected to a first connection wire 164a through a via. The first connection wire 164a may be positioned in a second build-up layer 130. In example embodiments, the first connection wire 164a may be connected to a wire 164 connected to a second via 162 contacting the first electrode 182.

The voltage transfer path will now be described.

As shown in FIG. 6, a voltage supplied from the semiconductor chip 210 may be transferred to the embedded decoupling capacitor 180 through the third topmost wires 148a and 148b, the first plane 141, the first connection wire 164a, the wire 164, and the second via 162.

Although not shown, a first voltage (for example, a ground voltage GND) may be transferred to the semiconductor chip 210 through a first external connection terminal 320, a first bottommost wire 168, a via 166, the wire 164, the first connection wire 164a, the first plane 141, the third topmost wires 148a and 148b, and a bump.

In particular, unlike the wires (for example, 144, 164, etc.) in different layers, the first plane 141 may be formed over a relatively wide area. Thus, the first plane 141 may have a relatively small resistance. Accordingly, inductance or resistance generated between the voltage terminal of the semiconductor chip 210 and the embedded decoupling capacitor 180 may be reduced.

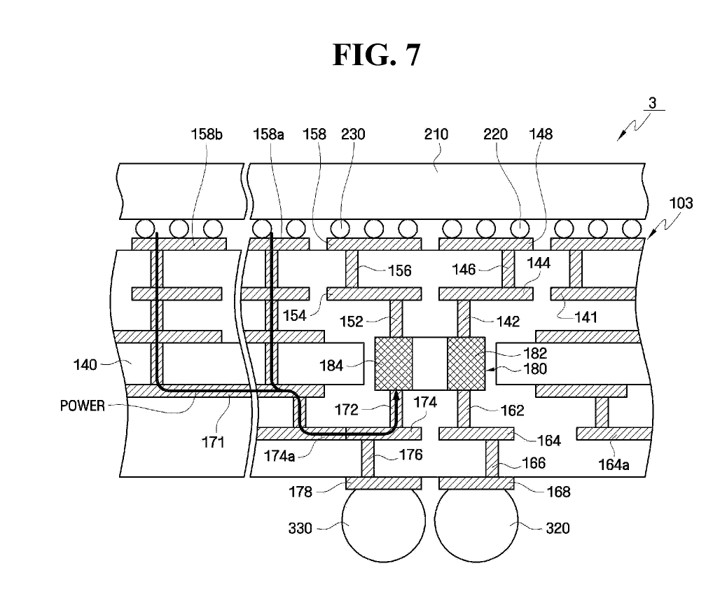

FIG. 7 is a cross-sectional view of a circuit board and a semiconductor package according to example embodiments. The following description will focus on differences between the circuit boards and the previously described semiconductor packages.

Referring to FIG. 7, in the semiconductor package 3 according to example embodiments, a second plane 171 in a circuit board 103 may be used as a voltage transfer path.

As shown in FIG. 7, fourth topmost wires 158a and 158b not overlapping with a second electrode 184 may be electrically connected to the second plane 171 through vias. The second plane 171 may be electrically connected to a second connection wire 174a through a via. In example embodiments, the second connection wire 174a may be connected to a wire 174 connected to a fourth via 172 contacting the second electrode 184.

The voltage transfer path will now be described.

As shown in FIG. 7, a voltage supplied from a semiconductor chip 210 may be transferred to an embedded decoupling capacitor 180 through the fourth topmost wires 158a and 158b, the second plane 171, the second connection wire 174a, and the fourth via 172.

Although not shown, a second voltage (for example, a power voltage POWER) may be transferred to the semiconductor chip 210 through a second external connection terminal 330, a second bottommost wire 178, a via 176, the wire 174, the second connection wire 174a, the second plane 171, the fourth topmost wires 158a and 158b, and a bump.

In particular, unlike the wires (for example, 144, 164, etc.) in different layers, the second plane 171 may be formed over a relatively wide area. Thus, the second plane 171 may have a relatively small resistance. Accordingly, inductance or resistance generated between the voltage terminal of the semiconductor chip 210 and the embedded decoupling capacitor 180 may be reduced.

FIG. 8 is a cross-sectional view of a circuit board according to example embodiments.

Referring to FIG. 8, a circuit board 108 according example embodiments may be substantially the same as the circuit board 101 illustrated in FIG. 1, except that it may be composed of four conductive layers.

In the circuit board 108, a topmost layer and a bottommost layer may be primarily used for transfer of signals, and two middle layers may be primarily used for transfer of voltages.

An embedded decoupling capacitor 180 may be formed in a core layer 110. The embedded decoupling capacitor 180 may include a first electrode 182 and a second electrode 184 in a direction in which they extend through the core insulation layer 140.

The first electrode 182 may contact a first via 142 formed in a first build-up layer 120 and may contact a second via 162 formed in a second build-up layer 130. With this configuration, a first bottommost wire 168 of the second build-up layer 130 and a first topmost wire 148 of the first build-up layer 120 may be connected to each other through the first electrode 182. That is to say, the first electrode 182 may serve as a wire.

The second electrode 184 may contact the third via 152 formed in the first build-up layer 120 and may contact a fourth via 172 formed in the second build-up layer 130. With this configuration, a second bottommost wire 178 of the second build-up layer 130 and a second topmost wire 158 of the first build-up layer 120 may be connected to each other through the second electrode 184. That is to say, the second electrode 184 may serve as a wire.

### Application Examples

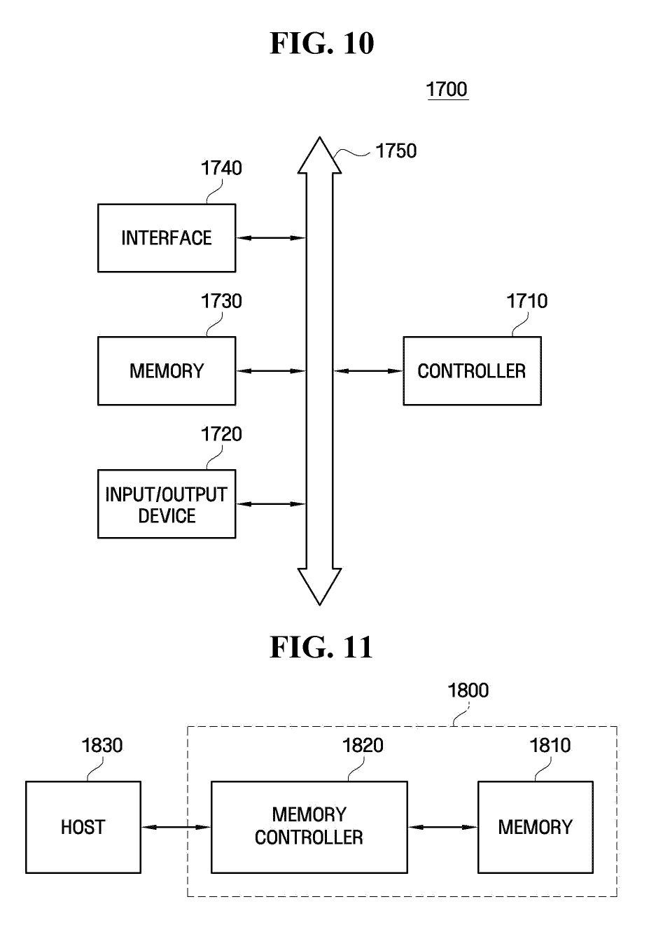

FIGS. 9 to 11 illustrate application examples of semiconductor packages according to example embodiments.

Referring to FIG. 9, the above-described semiconductor packages 1, 2, and 3, the circuit boards 101, 102, and 103 may be applied to a package module 1600 including various kinds of semiconductor devices. The package module 1600 may include a circuit board 1610 provided with a terminal 1640, a semiconductor chip 1620 mounted on the circuit board 1610, and a semiconductor chip 1630 packaged in a quad flat package (QFP) configuration. The semiconductor packages according to example embodiments may be applied to the semiconductor chips 1620 and 1630. The package module 1600 may be connected to an external electronic device through the terminal 1640.

Referring to FIG. 10, the above-described semiconductor packages 1, 2, and 3 may be applied to the electronic system 1700. The electronic system 1700 may include a controller 1710, an input and output (I/O) device 1720, and a memory device 1730. The controller 1710, the I/O device 1720, and the memory device 1730 may be coupled to each other via a bus 1750.

For example, the controller 1710 may include at least one micro process, digital signal process, microcontroller, and at least one of logic devices that can execute functions similar to these. The controller 1710 and the memory device 1730 may include the three-dimensional semiconductor packages 1, 2 and 3 according to the above-described embodiments. The I/O device 1720 may include at least one selected from a keypad, a keyboard, and a display device. The memory device 1730 may store data and/or instructions to be executed by the controller 1710.

The memory device 1730 may include a volatile memory device such as DRAM and/or a nonvolatile memory device such as a flash memory. For example, the flash memory may be mounted on an information processing system such as a mobile device or a desktop computer. The flash memory may be configured by a solid state semiconductor disk device (SSD). In example embodiments, the electronic system 1700 may stably store large-capacity data in a flash memory system.

The electronic system 1700 may further include an interface 1740 for transmitting data to a communication network or for receiving data from a communication network. The interface 1740 may be in the form of wire or wireless. For example, the interface 1740 may include an antenna or a wire/wireless transceiver. The electronic system 1700 may further include application chipset, a camera image processor (CIS), or an input/output device.

The electronic system 1700 may be embodied by a mobile system, a personal computer, an industrial computer, or a system carrying out various functions. For example, the mobile system may be a personal digital assistant (PDA), portable computer, web tablet, mobile phone, wireless phone, laptop computer, memory card, digital music system, or information transmitting/receiving system. The electronic system 1700 may be used in communication systems such as code division multiple access (CDMA), global system for mobile communication (GSM), North 20 American digital cellular (NADC), time division multiple access (TDMA), extended TDMA (ETDMA), wideband CDMA, or CDMA-2000 when the electronic system 1700 is equipment capable of carrying out wireless communication.

Referring to FIG. 11, the above-described semiconductor packages 1, 2, and 3 may be provided in the form of a memory card 1800. In example embodiments, the memory card 1800 may include a memory 1810, for example, a nonvolatile memory device, and a memory controller 1820. The memory 1810 and the memory controller 1820 may store data or read out data stored in the memory 1810. The memory 1810 may include at least one of nonvolatile memory devices to which semiconductor packages according to example embodiments are applied. The memory controller 1820 may control the memory 1810 to read out data stored in the memory device or to store data in the memory 1810 in response to read/write request from a host 1830.

While the present invention has been particularly shown and described with reference to example embodiments thereof, it will be understood by those of ordinary skill in the art that various changes in form and details may be made therein without departing from the spirit and scope of the present invention as defined by the following claims. It is therefore desired that example embodiments be considered in all respects as illustrative and not restrictive, reference being made to the appended claims rather than the foregoing description to indicate the scope of the invention.

1. A circuit board comprising:
a core layer including an embedded decoupling capacitor;
a first build-up layer on one side of the core layer; and
a second build-up layer on another side of the core layer,
wherein the embedded decoupling capacitor includes a first electrode and a second electrode, the first build-up layer includes a first via contacting the first electrode, and the second build-up layer includes a second via contacting the first electrode.

2. The circuit board of claim 1, wherein the first build-up layer includes a first topmost wire, the second build-up layer includes a first bottommost wire, and the first bottommost wire, the second via, the first electrode, the first via and the first topmost wire are arranged to form a first voltage supply path.

3. The circuit board of claim 1, wherein the core layer includes
a core insulation layer having the embedded decoupling capacitor therein, and
a first plane of a first voltage on the core insulation layer.

4. The circuit board of claim 3, wherein the first plane does not overlap the embedded decoupling capacitor.

5. The circuit board of claim 3, wherein the first build-up layer includes a plurality of second topmost wires not overlapping with the first electrode, and the plurality of second topmost wires being electrically connected to the first plane.

6. The circuit board of claim 5, wherein the second build-up layer includes a first connection wire electrically connected to the first plane, and the first electrode is electrically connected to the first connection wire through the second via.

7. The circuit board of claim 1, wherein the first build-up layer includes a third via contacting the second electrode, and the second build-up layer includes a fourth via contacting the second electrode.

8. The circuit board of claim 7, wherein the first build-up layer includes a third topmost wire, the second build-up layer includes a second bottommost wire, and the second bottommost wire, the fourth via, the second electrode, the third via and the third topmost wire are arranged to form a second voltage supply path.

9. The circuit board of claim 8, wherein the first build-up layer includes a first topmost wire, the second build-up layer includes a first bottommost wire, and the first bottommost wire, the second via, the first electrode, the first via and the first topmost wire are arranged to form a first voltage supply path.

10. The circuit board of claim 9, wherein the first bottommost wire overlaps with the first electrode and the second bottommost wire overlaps with the second electrode.

11. The circuit board of claim 1, wherein the embedded decoupling capacitor is a multi layer chip capacitor (MLCC).

12. The circuit board of claim 11, wherein the embedded decoupling capacitor includes an insulation body between the first electrode and the second electrode, and the insulation body includes multi-layered insulation layers and multi-layered inner electrodes between the multi-layered insulation layers and connected to one of the first electrode and the second electrode.

13. The circuit board of claim 1, further comprising:
a first topmost wire on the first build-up layer so as not to overlap with the first electrode, wherein the core layer includes a core insulation layer and a first plane of a first voltage on at least one side of the core insulation layer, the embedded decoupling capacitor is in the core insulation layer, and the first topmost wire is electrically connected to the first electrode through the first plane and a first connection wire in the second build-up layer.

14. (canceled)

15. (canceled)

16. The circuit board of claim 1, wherein the first build-up layer includes a first topmost wire, the second build-up layer includes a first bottommost wire, and the first bottommost wire, the second via, the first electrode, the first via and the first topmost wire are arranged to fond a first voltage supply path.

17. The circuit board of claim 13, wherein the first build-up layer includes a third via contacting the second electrode, and the second build-up layer include a fourth via contacting the second electrode.

18. The circuit board of claim 13, wherein the embedded decoupling capacitor is a multi layer chip capacitor (MLCC).

19. (canceled)

20. A circuit board comprising:
a core layer including a decoupling capacitor, the decoupling capacitor including a first electrode, a second electrode, and an insulation body between the first electrode and the second electrode;
a first buildup layer on an upper surface of the core layer, the first build up layer including a first wire and a second wire, the first wire being connected to the first electrode by a first via and the second wire being connected to the second electrode by a second via; and
a second buildup layer on a lower surface of the core layer, the second build up layer including a third wire and a fourth wire, the third wire being connected to the first electrode by a third via and the fourth wire being connected to the second electrode by a fourth via.

21. The circuit board of claim 20, wherein the first build up layer includes a first and a second top most wire and the second build up layer includes a first and a second bottom most wire, and the first top most wire is electrically connected the first bottom most wire by the first wire, the first via, and the first electrode, the third via, and the third wire, and the second top most wire is electrically connected to the second bottom most wire by the second wire, the second via, the second electrode, the fourth via, and the fourth wire.

22. The circuit board of claim 20, wherein the first build up layer includes a first and a second top most wire, the second build up layer includes fifth wire, and the core layer includes a first plane, and the first and second top most wires are connected to the first electrode by the first plane the fifth wire, the third wire, and the third via.
